(19) United States
(12) Patent Application Publication
(10) Pub. No.: US 2012/0257359 A1
(43) Pub. Date: Oct. 11, 2012

(54) Circuit Layout of Image Capturing Device

(75) Inventor: Yu-Bang Fu, Guishan Township (TW)

(73) Assignee: ALTEK CORPORATION, Hsinchu (TW)

(21) Appl. No.: 13/118,056

(22) Filed: May 27, 2011

(30) Foreign Application Priority Data
Apr. 8, 2011 (TW) 100112243

(51) Int. Cl. H05K 1/18

(52) U.S. Cl. 361/748

(57) ABSTRACT

A circuit layout of an image capturing device comprises a circuit board, an image capturing circuit, a flashlight circuit and a groove. The circuit board is a multilayered structure. The image capturing circuit is built on the circuit board. The flashlight circuit is built on the circuit board. The groove is formed on the multilayered structure of the circuit board and divides the circuit board into two areas where the image capturing circuit and the flashlight circuit are respectively disposed. The image capturing circuit is located at a first area, and the flash circuit is located at a second area. Therefore, the groove can prevent the interference between the image capturing circuit and the flashlight circuit.

### BACKGROUND OF THE INVENTION

1. Field of the Invention

The present invention relates to a circuit layout, and more particularly to a circuit layout of an image capturing device capable of preventing the signals of the photosensitive element from being interfered by charging of flashlight.

2. Description of the Related Art

Because of technology progress in digital products, 3C (computer, communication and consumer electronics) digital products are continuously provided and have low prices, so that consumer image capturing devices, such as a cell phone having a built-in camera, a smartphone and a digital camera, can be gradually in widespread use. More specifically, a traditional camera using film has been completely replaced with a convenient function of shoot-per-view in the digital camera, and people can quickly obtain taken images. Currently, the digital camera has been become a convenient tool in people's daily life or work.

Either a conventional optical camera or a digital camera is usually equipped with a flashlight for allowing a user to take a satisfied picture at a place where light is insufficient. Normally, the flashlight of the camera can be divided into two types: an external flashlight or a built-in flashlight (hidden type) inside the housing of the camera.

In a conventional technology, a flashlight circuit and a circuit of a photosensitive element such as a complementary metal-oxide-semiconductor (CMOS) or a charge-coupled-device (CCD) are usually separated at different circuit main boards. However, the foregoing manner may cause inefficiency in related space arrangement. Therefore, according to the actual application, designing a circuit layout of an image capturing device to avoid influencing signals of the photosensitive element due to the charging of the flashlight has become an important issue in market application.

### SUMMARY OF THE INVENTION

In view of the shortcomings of the prior art, the inventor(s) of the present invention based on years of experience in the related industry to conduct extensive researches and experiments, and finally developed a circuit layout of an image capturing device as a principle objective to overcome the problem of influencing signals of a photosensitive element due to the charging of a flashlight when a flashlight circuit and a photosensitive element circuit are designed at the same circuit main board.

To achieve the foregoing objective, a circuit layout of an image capturing device is provided and comprises a circuit main board, an image capturing circuit, a flashlight circuit and a groove. The image capturing circuit is disposed on the circuit main board. The flashlight circuit is disposed on the circuit main board. The groove is formed at the circuit main board and divides the circuit main board into two areas where the image capturing circuit and the flashlight circuit are respectively disposed. The image capturing circuit is located at a first area, and the flashlight circuit is located at a second area.

Preferably, a distance between the image capturing circuit and the flashlight circuit is above 4 millimeters.

Preferably, the flashlight circuit further comprises a high voltage coil, and a distance between the high voltage coil and the image capturing circuit is above 6 millimeters.

Preferably, the flashlight circuit further comprises a charging loop, and a distance between the charging loop and the image capturing circuit is above 4 millimeters.

Preferably, the circuit main board is a multilayered structure, and the groove is formed in the multilayered structure.

Preferably, a ground terminal of the image capturing circuit on the circuit main board and a ground terminal of the flashlight circuit on the circuit main board are physically divided by the groove into a first ground terminal and a second ground terminal

Preferably, the groove is utilized to avoid mutual interference between the image capturing circuit and the flashlight circuit.

The circuit layout of the image capturing device has the following advantages:

When the flashlight circuit and the photosensitive element circuit are designed at the same circuit main board, signals of the photosensitive element are easily influenced by a strong electric field effect caused by charging the flashlight. The circuit layout of the image capturing device can avoid influencing signals of the photosensitive element due to the strong electric field effect caused by charging the flashlight. Further, better usage of an inner space of a camera can be achieved.

### BRIEF DESCRIPTION OF THE DRAWINGS

FIG. 1 is a block diagram of an image capturing device in accordance with an embodiment of the invention;

FIG. 2 is a schematic diagram of a circuit layout of an image capturing device in accordance with an embodiment of the invention;

FIG. 3 is a cross-sectional diagram of a circuit main board of a multilayered circuit structure in accordance with an embodiment of the invention;

FIG. 4A is an appearance diagram of an image capturing device in accordance with a first embodiment of the invention; and

FIG. 4B is an appearance diagram of an image capturing device in accordance with a second embodiment of the invention.

### DETAILED DESCRIPTION OF THE PREFERRED EMBODIMENTS

The foregoing and other technical characteristics of the present invention will become apparent with the detailed description of the preferred embodiments and the illustration of the related drawings.

An image capturing device of the invention can be different kinds of portable electronic devices having photographing function such as a digital camera, a camera phone, a smartphone or a digital video camera. To understand the technical features of the invention, the following can take, but are not limited to, the camera phone as an embodiment.

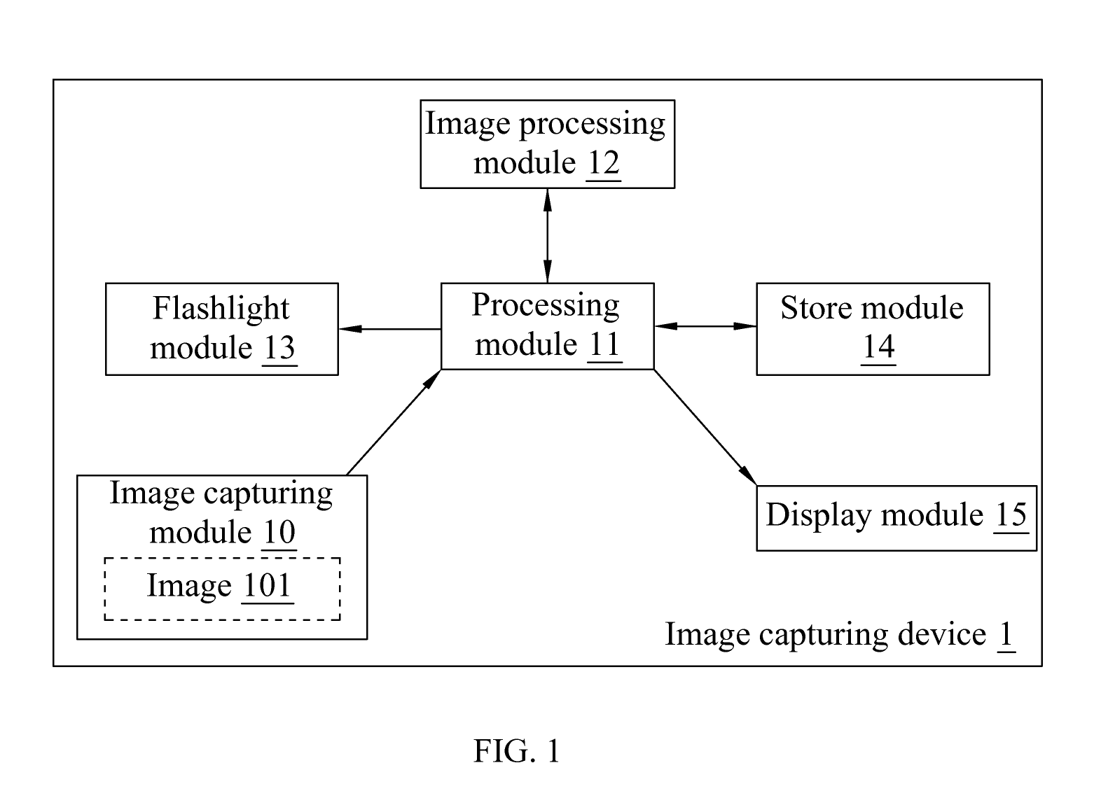

With reference to FIG. 1 for a block diagram of an image capturing device in accordance with an embodiment of the invention is depicted. As shown in the diagram, the image capturing device 1 of the invention comprises an image capturing module 10, a processing module 11, an image processing module 12, a flashlight module 13, a store module 14 and a display module 15. The image capturing module 10 can capture images and generate image data based upon a scene. The image capturing module 10 can include a camera lens, photosensitive elements such as a complementary-metal-oxide-semiconductor (CMOS) or a charge-coupled-device (CCD), an analog/digital circuit, an image processor, etc.

The processing module 11 is electrically connected to the image capturing module 10, the image processing module 12, the flashlight module 13, the store module 14 and the display module 15 and can be a central processing unit (CPU) or a micro-processing unit. A user can control the flashlight module 13 to flash light through the processing module 11 according to the brightness at the photographing spot. The images 101 captured by image capturing module 10 can be saved in the store module 14 and displayed on the display module 15 after processed by the image processing module 12. Preferably, the store module 14 can be an embedded memory, an external memory card or a combination thereof. The display module 15 can be a liquid crystal display (LCD) or a touch LCD.

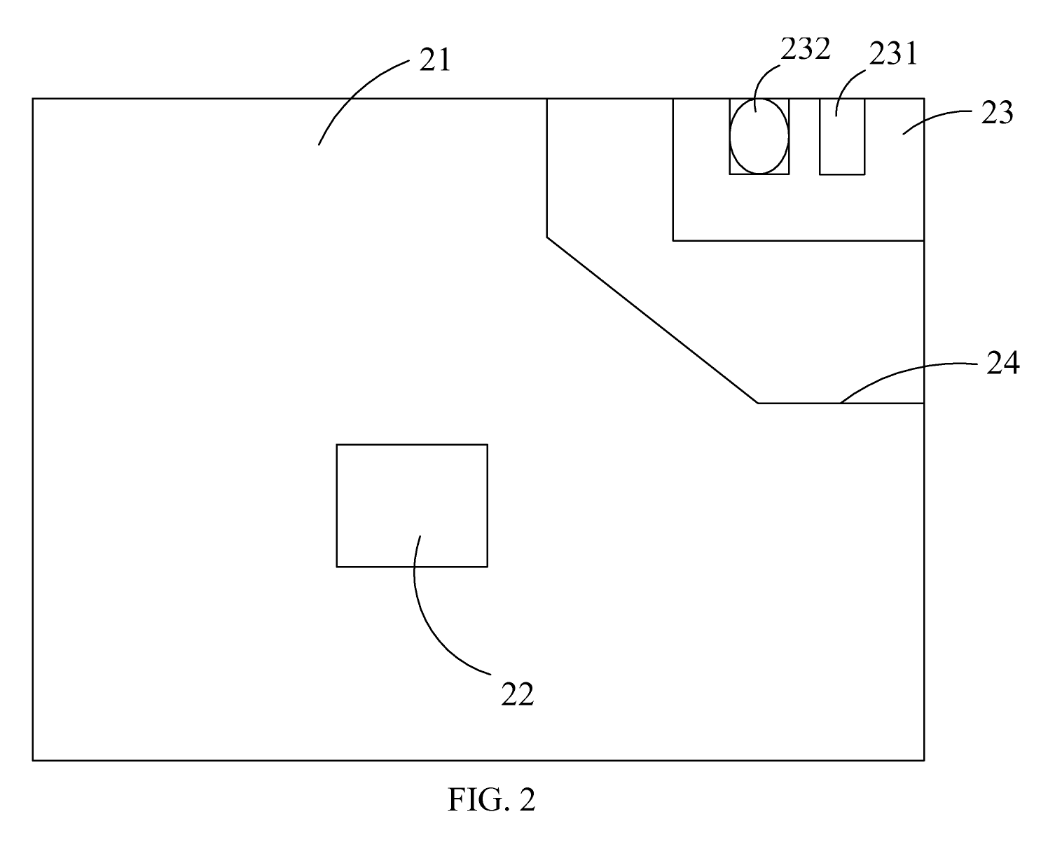

With reference to FIG. 2 for a schematic diagram of a circuit layout of an image capturing device in accordance with an embodiment of the invention is depicted. The circuit layout of the image capturing device of the invention comprises a circuit main board 21, an image capturing circuit 22, a flashlight circuit 23 and a groove 24. The circuit main board 21 is preferably a multilayered circuit structure. In the embodiment, the image capturing circuit 22 is preferably a photosensitive element such as a complementary-metal-oxide-semiconductor (CMOS) or a charge-coupled-device (CCD) and can be disposed at a position near a central point of the circuit main board 21. The foregoing position of the image capturing circuit 22 is an example instead of a limitation. The flashlight circuit 23 is preferably disposed at one corner of the circuit main board 21 and can further include a high voltage coil 231 and a charging loop 232 (or a charger). The high voltage coil 231 and a charging loop 232 can be disposed near a periphery of the circuit main board 21.

The groove 24 can be formed in the multilayered structure of the circuit main board 21 to divide the circuit main board 21 into two areas where the image capturing circuit 22 and the flashlight circuit 23 are respectively disposed. The image capturing circuit 22 can be at a first area. The flashlight circuit 23 can be at a second area. A distance between the image capturing circuit 22 and the flashlight circuit 23 can be above 4 millimeters. A distance between the high voltage coil 231 and the image capturing circuit 22 can be above 6 millimeters. A distance between the charging loop 232 and the image capturing circuit 22 can be above 4 millimeters.

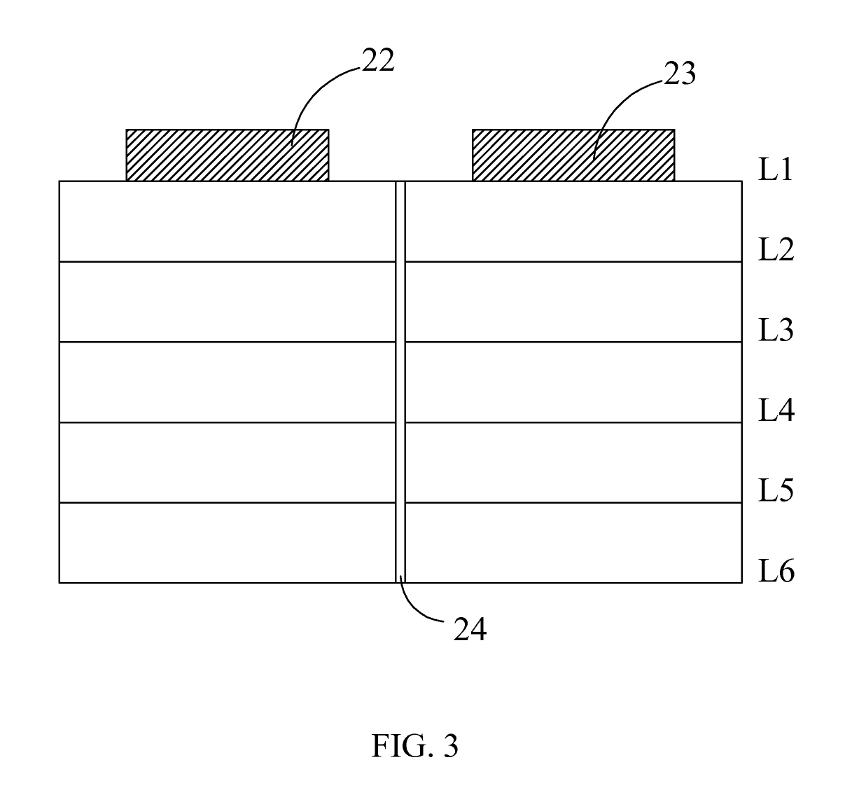

With reference to FIG. 3 for a cross-sectional drawing of a circuit main board of a multilayered circuit structure in accordance with an embodiment of the invention is depicted. The circuit main board of the multilayered circuit structure can be divided into six layered structure from L1 to L6, wherein ground terminals can be installed on the second layer L2 and the sixth layer L6. Other necessary circuits can be installed on the other layers. However, it should be noted that the ground terminal of the image capturing circuit 22 at the circuit main board 21 and the ground terminal of the flashlight circuit 23 at the circuit main board 21 can be divided by the groove 24 into a first ground terminal and a second ground terminal. In another word, in the six layered structures of the circuit main board, only necessary circuits are installed between the image capturing circuit 22 and the flashlight circuit 23. The ground terminals of the image capturing circuit 22 and the flashlight circuit 23 are individually installed at different positions. Accordingly, the surface copper foil of the flashlight circuit 23 can be separated from the image capturing circuit 22. The mutual interference between the image capturing circuit 22 and the flashlight circuit 23 can be avoided through the groove 24. For example, noise interference, such as common mode noise or simultaneous switching noise, can be prevented.

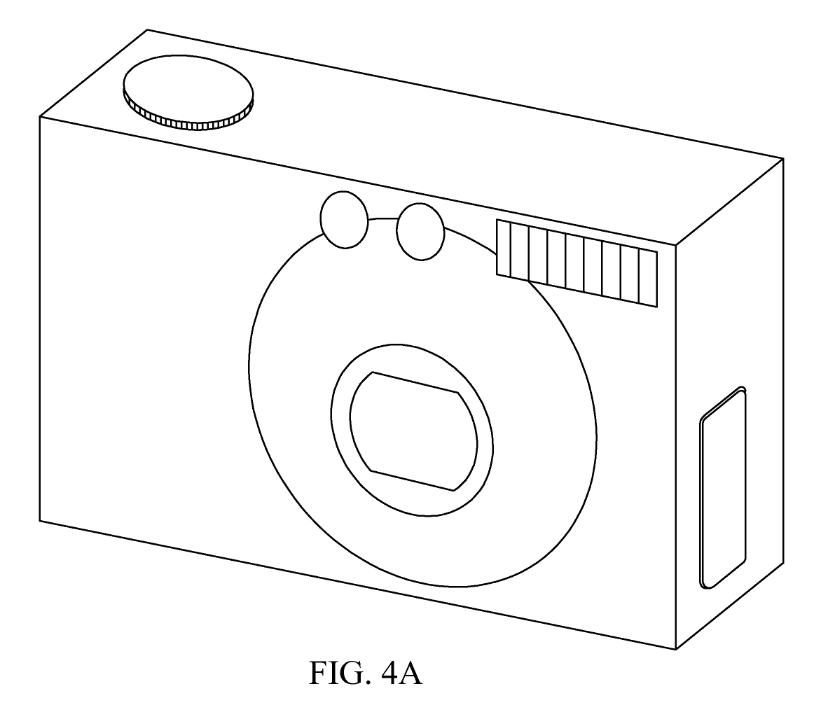

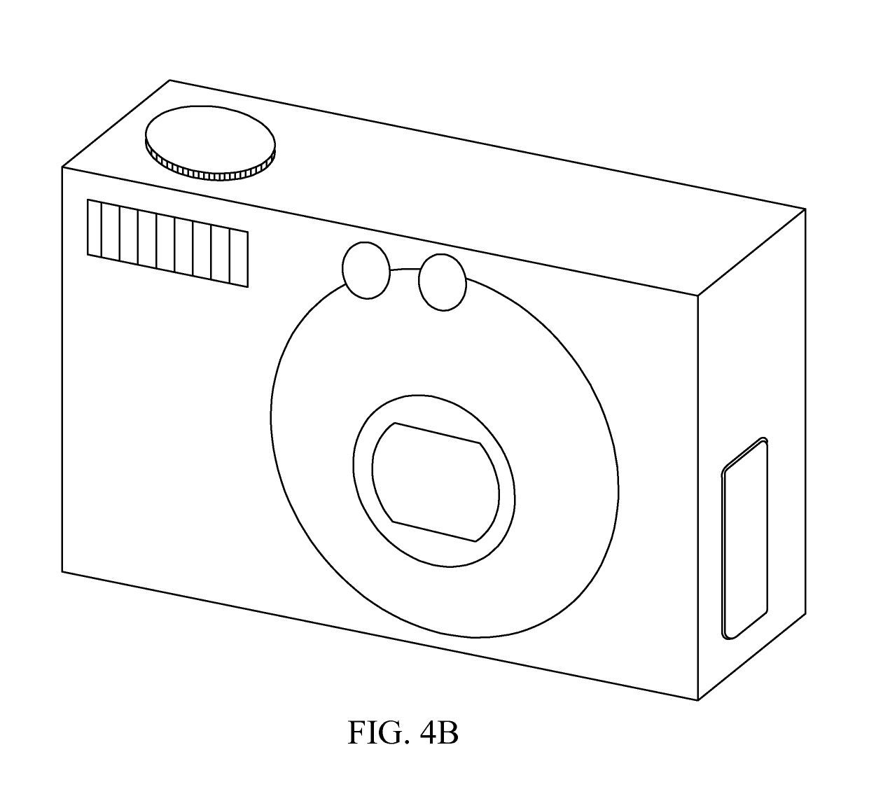

With reference to FIG. 4A and FIG. 4B, FIG. 4A is an appearance diagram of an image capturing device in accordance with a first embodiment of the invention, and FIG. 4B is an appearance diagram of an image capturing device in accordance with a second embodiment of the invention. The flashlight circuit 23 of the circuit layout of the image capturing device can be preferably disposed at one corner of the circuit main board 21, such as the upper right corner (as shown in FIG. 4A) or the upper left corner (as shown in FIG. 4B). The position of flashlight circuit 23 can be varied according to actual application or users' preferences. The foregoing positions of the flashlight circuit 23 are examples instead of limitations. In practice, the scope of the present invention is not limited to the foregoing configuration.

When the flashlight circuit and the photosensitive element are designed at the same circuit main board, signals of the photosensitive element are easily influenced by the strong electric field effect caused by charging the flashlight. The circuit layout of the image capturing device can avoid influencing the signals of the photosensitive element due to the strong electric field effect caused by charging the flashlight. Further, better usage of the inner space of the camera can be achieved.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A circuit layout of an image capturing device comprising:
a circuit main board;
an image capturing circuit disposed on the circuit main board;
a flashlight circuit disposed on the circuit main board; and
a groove formed over the circuit main board and dividing the circuit main board into two areas where the image capturing circuit and the flashlight circuit are respectively disposed, wherein the image capturing circuit is at a first area, and the flashlight circuit is at a second area.

2. The circuit layout of an image capturing device as recited in claim 1, wherein a distance between the image capturing circuit and the flashlight circuit is above 4 millimeters.

3. The circuit layout of an image capturing device as recited in claim 1, wherein the flashlight circuit further comprises a high voltage coil, and a distance between the high voltage coil and the image capturing circuit is above 6 millimeters.

4. The circuit layout of an image capturing device as recited in claim 1, wherein the flashlight circuit further comprises a charging loop, and a distance between the charging loop and the image capturing circuit is above 4 millimeters.

5. The circuit layout of an image capturing device as recited in claim 1, wherein the circuit main board is a multilayered structure, and the groove is formed in the multilayered structure.

6. The circuit layout of an image capturing device as recited in claim 1, wherein a ground terminal of the image capturing circuit on the circuit main board and a ground terminal of the flashlight circuit on the circuit main board are physically divided by the groove into a first ground terminal and a second ground terminal.

7. The circuit layout of an image capturing device as recited in claim 1, wherein the groove is utilized to avoid mutual interference between the image capturing circuit and the flashlight circuit.

8. The circuit layout of an image capturing device as recited in claim 1, wherein the second area is disposed at one corner of the circuit main board.

9. The circuit layout of an image capturing device as recited in claim 1, wherein the flashlight circuit further includes a high voltage coil and a charging loop, and the high voltage coil and the charging loop are disposed on a periphery of the circuit main board.

10. The circuit layout of an image capturing device as recited in claim 1, wherein the image capturing circuit is a photosensitive element, such as a complementary metal-oxide-semiconductor or a charge-coupled-device.
